(19) United States
(12) Patent Application Publication
(10) Pub. No.: US 2003/0178215 A1
(43) Pub. Date: Sep. 25, 2003

(54) Electromagnetic interference prevention structure for signal cable

(75) Inventors: Kuo-Cheng Chu, Taipei (TW); Mao-Sheng Huang, Taipei (TW)

Correspondence Address: BACON & THOMAS, PLLC, 625 SLATERS LANE, FOURTH FLOOR, ALEXANDRIA, VA, 22314

(73) Assignee: COMPAL ELECTRONICS, INC., Taipei (TW)

(21) Appl. No.: 10/103,287

(22) Filed: Mar. 22, 2002

(51) Int. Cl. H05K 9/00

(52) U.S. Cl. 174/35 C

(57) ABSTRACT

An electromagnetic interference (EMI) prevention structure for a signal cable, which has at least one signal wire, a plurality of shielding wires, an intermediate layer located between the signal wire and the shielding wires, and an outer layer covering the shielding wires, includes a plurality of grounding areas formed on the outer layer of the signal cable by re-distributing or removing some parts of the structural mass of the outer layer at predetermined intervals or at predetermined positions. Whereby any noise voltage produced on the signal cable across any section thereof is effectively removed via one of the grounding areas that is closest to the section at where the noise voltage is produced.

### BACKGROUND OF THE INVENTION

1. Field of the Invention

The present invention relates to an electromagnetic interference (EMI) prevention structure for signal cable, and more particularly to an EMI prevention structure for signal cable, in which a plurality of open grounding areas are formed on an insulating layer of the signal cable to contact with a grounding pole, so as to effectively reduce noise voltage produced on the signal cable and improve the quality of signal transmitted via the signal cable.

2. Description of the Prior Art

FIG. 1 shows an example of use of a conventional signal cable 1 on an electronic apparatus 2. The signal cable 1 mainly includes a signal wire 11 forming a core thereof, a plurality of shielding wires 12 surrounding an outer periphery of the signal wire 11, an intermediate layer 13 located between the signal wire 11 and the shielding wires 12, and an insulating layer 14 covering the shielding wires 12. The signal cable 1 is connected at an end to a circuit unit 21 of the electronic apparatus 2 to provide the latter with the function of signal transmission.

Noise voltage is frequently produced when signal current flows through the signal cable 1. The noise voltage is produced because high potential continuously flows toward low potential across the signal cable 1. That is, the noise voltage continuously forces from the inner signal wire 11 toward the outer insulating layer 14 and even penetrates the insulating layer 14 to reach an outer side thereof, resulting in interference with signals transmitted over other nearby cables due to mutual electromagnetic induction. This kind of electromagnetic interference (EMI) would adversely affect the stability of signals transmitted over the entire signal cable.

Therefore, it is a common practice in the communication industries to strip off a small length of the insulating layer 14 of the signal cable 1 near the end connected to the circuit unit 21, so that the shielding wires 12 could be extended from the signal cable 1 and bound up with a grounding terminal 15, which is then screwed to a predetermined grounded surface. In the illustrated FIG. 1, the predetermined grounded surface is a grounding plate 22 provided on the electronic apparatus 2. In this way, noise voltage produced when the signal wire 11 transmits signals is converged through magnetization of the signal wire 11 and then removed through grounding.

However, the above-described way does not meet the expectation when it is put into practical use. The insulating layer 14 does not effectively screen off the noise voltage and the produced noise voltage can be removed only via the grounding terminal 15 connected to one end of the signal cable 1. Noise voltage produced at middle section of the signal cable 1 or at other areas of the signal cable 1 distant from the grounding terminal 15 is not effectively removed due to long conducting distance from the grounding terminal 15 and tends to accumulate. After a period of time, the accumulated noise voltage would still penetrate the nearby insulating layer 14 to reach an outer side of the signal cable 1, resulting in unstable transmission and poor quality of signal over the signal cable 1.

It is therefore tried by the inventor to develop an improved EMI prevention structure for signal cable to eliminate drawbacks existing in the conventional signal cable.

### SUMMARY OF THE INVENTION

A primary object of the present invention is to provide an EMI prevention structure for signal cable. The signal cable includes at least one signal wire, a plurality of shielding wires surrounding each signal wire, an intermediate layer located between each signal wire and the shielding wires, and an outer layer covering the shielding wires. The signal cable has structural and material masses distributed in a new manner, so that some parts of the outer layer of the signal cable are removed to provided more than one grounding areas distributed at predetermined intervals or positions along the signal cable. When these grounding areas are in contact with a grounding pole, multiple ground points are formed on the signal cable. Any noise voltage produced on any section of the signal cable can be grounded and accordingly removed via the closest possible grounding area to ensure high-quality transmission of signals.

Another object of the present invention is to provide an EMI prevention structure for a signal cable having two signal wires. The two signal wires separately provide main and return paths for a common-mode current of an electronic apparatus.

A further object of the present invention is to provide an EMI prevention structure for signal cable, in which the signal cable is provided at an outer layer with a plurality of grounding areas. The grounding areas are tightly attached to a grounding pole with a plurality of clamping members made of a conductive material, such as iron, silver, etc., so that noise voltage produced on the signal cable at different sections can be guided to and removed from the grounding areas via the clamping members.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 shows an example of use of a conventional signal cable;

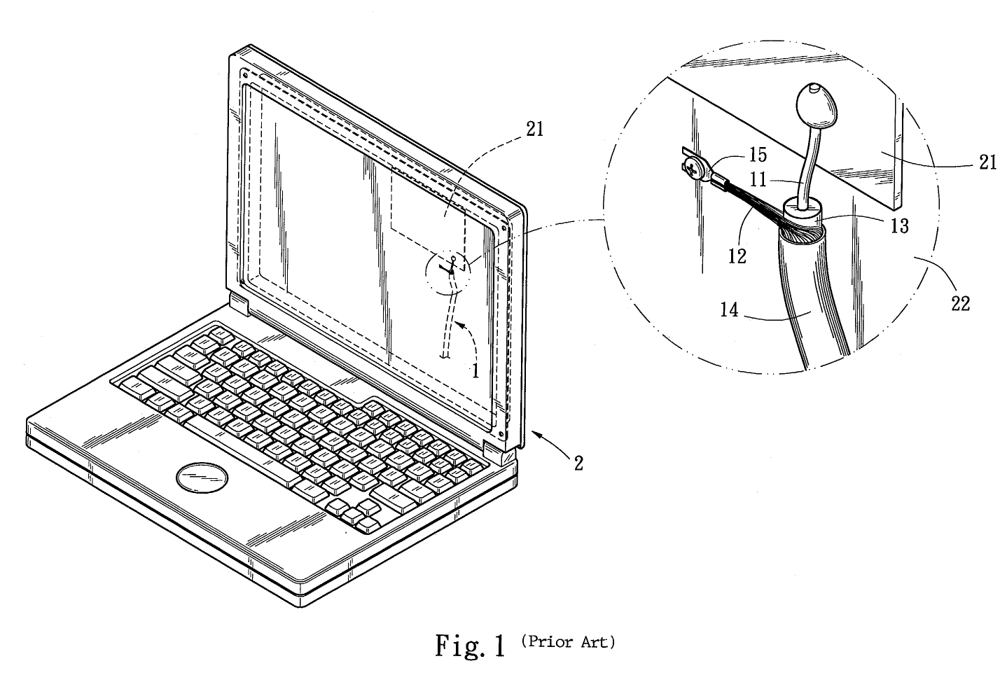

FIG. 2 is a perspective view of a signal cable having the EMI prevention structure according to the present invention; and

FIG. 3 shows an example of use of the signal cable of the present invention.

### DETAILED DESCRIPTION OF THE PREFERRED EMBODIMENTS

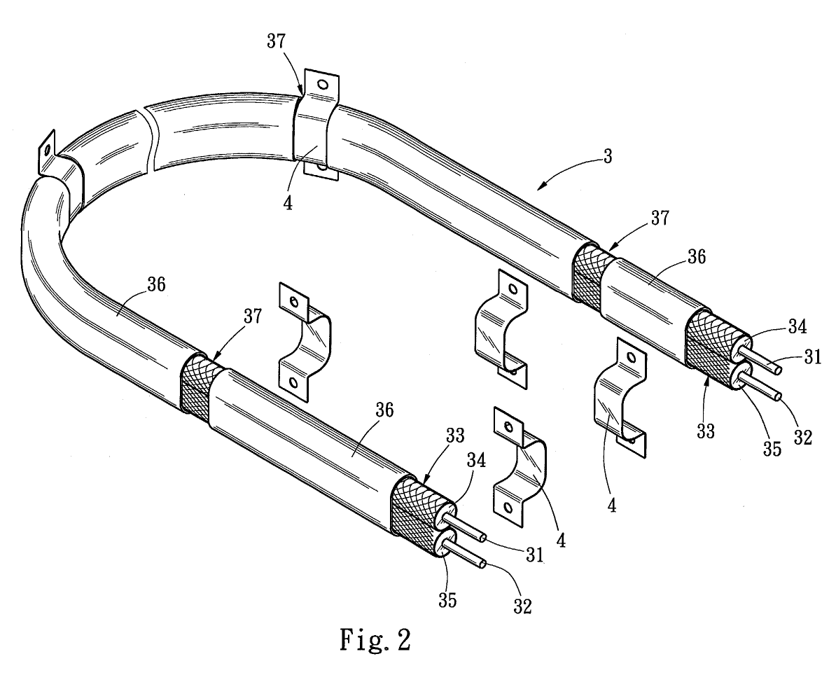

Please refer to FIG. 2 that is a perspective view of a signal cable 3 having the EMI prevention structure according to an embodiment of the present invention. As shown, the signal cable 3 includes at least two signal wires 31, 32 that provide main and return paths, respectively, for a common-mode current of an electronic apparatus; shielding wires 33 covering outer peripheries of each of the signal wires 31, 32; intermediate layers 34, 35 located between the signal wires 31, 32 and the shielding wires 33, respectively; and an outer layer 36 covering over the shielding wires 33. The two signal wires 31, 32 are axially adjacent to and parallel to each other and enclosed in a space defined by the outer layer 36.

In the illustrated embodiment, the intermediate layers 34, 35 and the outer layer 36 are made of a non-conductive material, such as rubber or plastics, and the two signal wires 31, 32 and the shielding wires 33 are made of a conductive material, such as iron, silver, and other suitable metals.

In a preferred embodiment of the present invention, the outer layer 36 has a structural mass that has been distributed in a new manner. That is, some parts of material mass of the outer layer 36 at predetermined positions or spaced at predetermined intervals are removed to form a plurality of grounding areas 37 along the signal cable 3. Multiple ground points are therefore provided on the shielding wires 33 at where the grounding areas 37 contact with a predetermined grounding pole, such as a housing of the electronic apparatus 2. Any noise voltage produced at a certain section of the signal cable 3 can therefore be removed via a closest possible grounding area 37 on the signal cable 3 to ensure high-quality signal transmission via the signal cable 3.

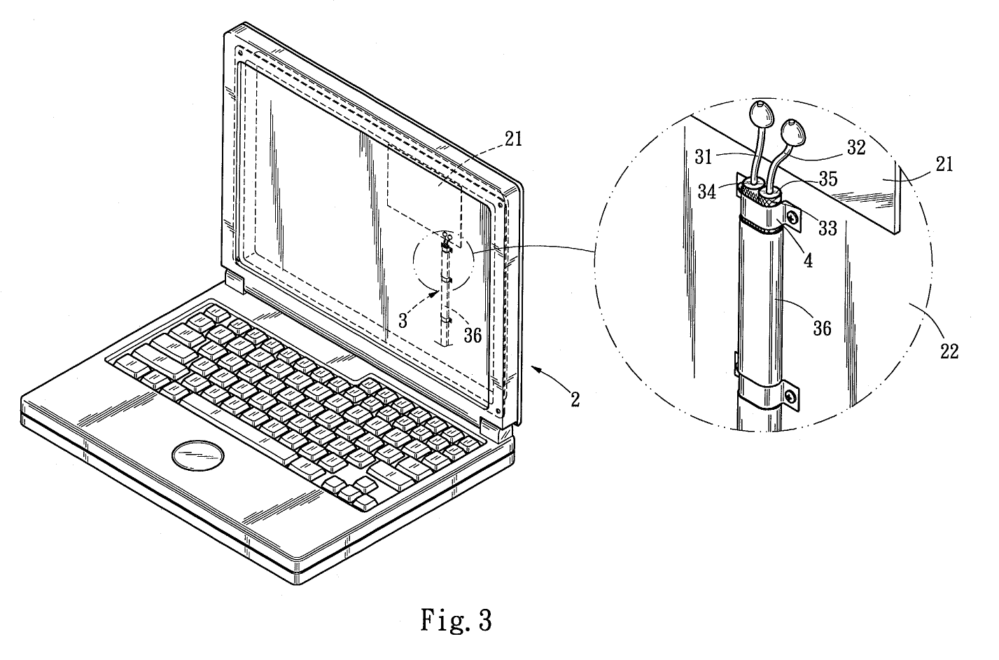

Please refer to FIGS. 2 and 3 at the same time. In the illustrated embodiment of the present invention, there are also provided a plurality of clamping members 4 for correspondingly tightly attaching to the grounding areas 37. The clamping members 4 are made of a conductive material, such as iron, silver or other suitable metals, and are separately located between the grounding areas 37 and the grounding pole, such as the housing of the electronic apparatus 2. The clamping members 4 may have a profile corresponding to that of the grounding areas 37 to which they are tightly attached. In the illustrated embodiment, the clamping members 4 have a profile close to a letter n, in order to obtain an increased contact area with the shielding wires 33. The clamping members 4 are then screwed, welded, clamped or connected in any other equivalent manner to the grounding pole. In the illustrated drawings, the grounding pole is a plate 22 forming a part of the electronic apparatus 2.

With the outer layer 36 having at least some parts of its structural mass being removed, as described above, any noise voltage received by the shielding wires 33 at a certain section of the signal cable 3 may be guided to and removed from the closest possible grounding area 37, enabling effective reduction of EMI and mutual cancellation of magnetic flux. Moreover, the signal cable 3 with multiple ground points as provided by the present invention may have effectively reduced ground impedance that facilitates backflow of RF current of high-frequency signals.

The present invention has been described with a preferred embodiment thereof and it is understood that many changes and modifications in the described embodiment can be carried out without departing from the scope and the spirit of the invention as defined by the appended claims.

What is claimed is:

1. An electromagnetic interference (EMI) prevention structure for signal cable, said signal cable including at least a signal wire, a plurality of shielding wires surrounding an outer periphery of said at least one signal wire, an intermediate layer located between each said signal wire and said shielding wires, and an outer layer covering an outer periphery of said shielding wires; said EMI prevention structure for signal cable comprising more than one grounding areas formed on said outer layer of said signal cable at predetermined intervals or at predetermined positions, whereby any noise voltage produced on said signal cable across any section thereof is effectively removed via one of said grounding areas that is closest to said section at where said noise voltage is produced.

2. The EMI prevention structure for signal cable as claimed in claim 1, wherein said signal cable includes two signal wires that separately provide main and return paths for a common-mode current of an electronic apparatus to which said signal cable is connected.

3. The EMI prevention structure for signal cable as claimed in claim 1, wherein said intermediate layer and said outer layer are made of a non-conductive material.

4. The EMI prevention structure for signal cable as claimed in claim 1, wherein said at least one signal wire and said shielding wires are made of a conductive material.

5. The EMI prevention structure for signal cable as claimed in claim 1, further comprises a plurality of clamping members for separately locating between said grounding areas and a grounding pole to provide paths for removing said noise voltage.

6. The EMI prevention structure for signal cable as claimed in claim 5, wherein said clamping members are made of a conductive material and have a profile suitable for correspondingly tightly attaching said grounding areas to said grounding pole.

7. The EMI prevention structure for signal cable as claimed in claim 6, wherein said clamping members have a profile close to a letter n.
